(19) United States
(12) Patent Application Publication
(10) Pub. No.: US 2025/0107357 A1
(43) Pub. Date: Mar. 27, 2025

(54) OLED DISPLAY PANELS AND TERMINAL DEVICES

(71) Applicant: WUHAN CHINA STAR OPTOELECTRONICS SEMICONDUCTOR DISPLAY TECHNOLOGY CO., LTD., Wuhan (CN)

(72) Inventor: Tao CHEN, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 18/523,954

(22) Filed: Nov. 30, 2023

Related U.S. Application Data
(63) Continuation of application No. PCT/CN2023/123159, filed on Oct. 7, 2023.

(30) Foreign Application Priority Data
Sep. 25, 2023 (CN) 202311246067.9

(51) Int. Cl. H10K 59/131; H10K 59/121; H10K 59/35

(52) U.S. Cl. CPC H10K 59/131; H10K 59/121; H10K 59/35

(57) ABSTRACT

Embodiments of the present disclosure disclose an OLED display panel and a terminal device. The OLED display panel includes power signal lines and vertical auxiliary lines extending along a first direction, and horizontal auxiliary lines and reset signal lines extending along a second direction. The horizontal auxiliary lines are electrically connected to the power signal lines at intersections therebetween to form a grid-like connection, and/or the vertical auxiliary lines are electrically connected to the reset signal lines at intersections therebetween to form grid-like connection.

### CROSS-REFERENCE TO RELATED APPLICATION

This application is a continuation of International Application No. PCT/CN2023/123159, filed on Oct. 7, 2023, which claims priority to and the benefit of Chinese Patent Application No. 202311246067.9, filed on Sep. 25, 2023. The disclosures of the aforementioned applications are incorporated herein by reference in their entireties.

### TECHNICAL FIELD

The present disclosure relates to the field of display technologies, and more particularly, to organic light emitting diode (OLED) display panels and terminal devices.

### BACKGROUND

Fanout in Active Area (FIAA) technology is an important technology for realizing a narrow lower border of an organic light emitting diode (OLED) display panel. The principle of FIAA is mainly to arrange some fanout traces to pass through a display area of the OLED display panel in a vertical direction, and then route the fanout traces in a horizontal direction to corresponding data lines, so as to narrow the lower border. One feature of this technology is that based on a general pixel design, horizontal and vertical metal traces are additionally provided in the display area near the lower border for routing the fanout traces in the display area. However, in an actual design only some metal traces are used for routing the fanout traces, and the remaining metal traces located in the display area near the lower border are not fully utilized and are left idle.

Therefore, the OLED display panels may have poor display uniformity.

### SUMMARY

According to some embodiments, the present disclosure provides an organic light emitting diode (OLED) display panel having a display area and a non-display area. The OLED display panel includes:
a substrate;
a plurality of power signal lines, a plurality of data signal lines, a plurality of reset signal lines disposed above the substrate;
a plurality of fanout traces disposed above the substrate, wherein the fanout traces comprises a plurality of first fanout traces and a plurality of second fanout traces, the first fanout traces are arranged in the display area, the second fanout traces are arranged in the non-display area, first end of each first fanout trace is electrically connected to one data signal line of the data signal lines, and second end of the each first fanout trace is electrically connected to one second fanout trace of the second fanout traces; and
a plurality of auxiliary traces disposed as an array in the display area above the substrate, wherein the auxiliary traces comprise a plurality of vertical auxiliary lines and a plurality of horizontal auxiliary lines, the vertical auxiliary lines are disposed in a layer different from a layer where the horizontal auxiliary lines are disposed, the vertical auxiliary lines and the power signal lines extend along a first direction, the horizontal auxiliary lines and the reset signal lines extend along a second direction, and the first direction and the second direction are perpendicular to each other;
wherein the horizontal auxiliary lines are disposed in a layer different from a layer wherein the power signal lines are disposed, the vertical auxiliary lines are disposed in a layer different from a layer wherein the reset signal lines are disposed, the horizontal auxiliary lines in parallel are electrically connected with the power signal lines in parallel at intersections therebetween, and/or the vertical auxiliary lines in parallel are electrically connected to the reset signal lines in parallel at intersections therebetween to form a grid-like connection.

According to some embodiments, the present disclosure provides a terminal device including the OLED display panel as described above.

### BRIEF DESCRIPTION OF THE DRAWINGS

In order to more clearly illustrate technical solutions in some embodiments of the present disclosure, the drawings for description of the embodiments will be briefly introduced below. Apparently, the drawings in the following description are only some embodiments of the present disclosure. For those skilled in the art, other drawings can also be obtained based on these drawings without creative efforts.

FIG. 1 is a schematic cross-sectional view of an organic light emitting diode (OLED) display panel using a fanout in Active Area (FIAA) design according to some embodiments of the present disclosure.

FIG. 2 is a schematic cross-sectional view of an OLED display panel according to some embodiments of the present disclosure.

FIG. 3 is a schematic cross-sectional view of another OLED display panel according to some embodiments of the present disclosure.

FIG. 4 is a schematic diagram of a circuit structure of a single-reset-signal pixel drive circuit used in the another OLED display panel according to some embodiments of the present disclosure.

FIG. 5 is a schematic cross-sectional view of yet another OLED display panel according to some embodiments of the present disclosure.

FIG. 6 is a schematic diagram of a circuit structure of a dual-reset-signal pixel drive circuit used in the yet another OLED display panel according to some embodiments of the present disclosure.

FIG. 7 is a schematic cross-sectional view of still another OLED display panel according to some embodiments of the present disclosure.

FIG. 8 is a schematic diagram of a circuit structure of a three-reset-signal pixel drive circuit used in the still another OLED display panel according to some embodiments of the present disclosure.

### DETAILED DESCRIPTION

The technical solutions in the embodiments of the present disclosure will be clearly and completely described below with reference to the accompanying drawings in the embodiments of the present disclosure. Obviously, the described embodiments are only some of the embodiments of the present disclosure, rather than all of the embodiments. Based on the embodiments in present disclosure, all other embodiments obtained by those skilled in the art without making creative efforts fall within the scope of protection of present disclosure. In addition, it should be understood that the specific embodiments described here are only used to illustrate and explain the present disclosure, and are not used to limit the present disclosure. In the present disclosure, unless otherwise specified, the directional words used such as “upper” and “lower” usually refer to upper and lower positions of a device in actual use or working conditions, specifically, a direction of a drawing in the drawings. “Inside” and “outside” refer to an outline of the device.

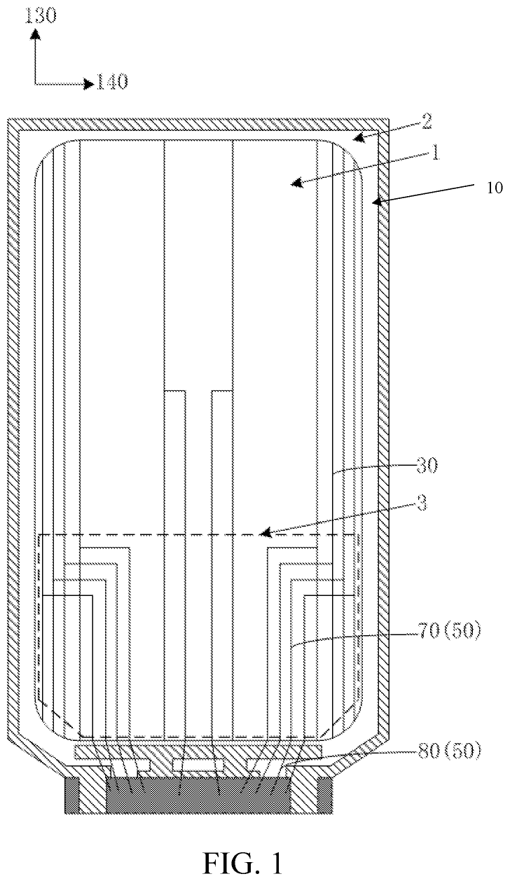

Please refer to FIGS. 1 to 8. An organic light emitting diode (OLED) display panel provided by some embodiments of the present disclosure has a display area 1 and a non-display area 2. The OLED display panel includes a substrate 10, and a plurality of power signal lines 20, a plurality of data signal lines 30, a plurality of reset signal lines 40, a plurality of fanout traces 50, and a plurality of auxiliary traces 60. The power signal lines 20, the data signal lines 30, the reset signal lines 40, the fanout traces 50, and the auxiliary traces 60 are disposed above the substrate 10. The fanout traces 50 each include a first fanout trace 70 and a second fanout trace 80. The first fanout traces 70 are arranged in a first area 3 of the display area 1. The second fanout traces 80 are arranged in the non-display area 2. One end of each first fanout trace 70 is electrically connected to one of the data signal lines 30, and the other end of the each first fanout trace 70 is electrically connected to one of the second fanout traces 80. The auxiliary traces 60 include a plurality of vertical auxiliary lines 601 and a plurality of horizontal auxiliary lines 602, where the vertical auxiliary lines 601 are disposed in a layer different from a layer where the horizontal auxiliary lines 602 are disposed. The vertical auxiliary lines 601 and the power signal lines 20 extend along a first direction 130. The horizontal auxiliary lines 602 and the reset signal lines 40 extend along a second direction 140. The first direction 130 and the second direction 140 are perpendicular to each other. The horizontal auxiliary lines 602 are disposed in a layer different from a layer where the power signal lines 20 are disposed. The vertical auxiliary lines 601 are disposed in a layer different from a layer where the reset signal lines 40 are disposed. The horizontal auxiliary lines 602 and the power signal lines 20 are electrically connected at intersections therebetween to form a grid-like connection, and/or the vertical auxiliary lines 601 and the reset signal lines 40 are electrically connected at intersections therebetween to form a grid-like connection.

Some metal traces in the first area 3 of the display area 1 are used as the auxiliary traces 60, where the horizontal auxiliary lines 602 and the power signal lines 20 are electrically connected at intersections therebetween to form a grid-like connection, and/or, the vertical auxiliary lines 601 and the reset signal lines 40 are electrically connected at intersections therebetween to form a grid-like connection. The grid-like connection formed by the auxiliary traces 60 and the power signal lines 20 and/or the reset signal lines 40 reduces impedance of the power signal lines 20 and/or impedance of the reset signal lines 40, thereby improving display uniformity.

In some embodiments of the present disclosure, only some metal traces in the first area 3 of the display area 1 that are not used as the fanout traces 50 are taken as the auxiliary traces 60 as an example for illustration. There are unused metal traces in other areas of the display panel. The unused metal traces may use the inventive concept of the present application, which should also fall within the protection scope of the present application. The unused metal traces may be connected in parallel with signal lines in need of impedance reduction, such as the power signal lines 20 and the reset signal lines 40, thereby improving the display uniformity.

It should be noted that in order to arrange the first fanout traces 70 in the display area 1, metal traces need to be prepared in the first area 3 of the display area 1 in advance. The metal traces include a plurality of first metal traces extending along the first direction 130 and a plurality of second metal traces extending along the second direction 140. Some first metal traces are used as a plurality of first traces 701 and some second metal traces are used as a plurality of second traces 702. The first traces 701 and the second traces 702 are connected through first vias 90 to form the first fanout traces 70. Further, the present disclosure can use the remaining metal traces that are not used as the first fanout traces 70 as auxiliary traces. Specifically, the remaining first metal traces that are not used as the first traces 701 may be used as the vertical auxiliary lines 601, and the remaining second metal traces that are not used as the second traces 702 may be used as the horizontal auxiliary lines 602.

It should be noted that the electrical connection may be a parallel connection, the vertical auxiliary lines 601 in parallel are connected with the reset signal lines 40 in parallel through the third vias 110 at the intersections between the vertical auxiliary lines 601 and the reset signal lines 40, and the horizontal auxiliary lines 602 are connected in parallel between the power signal lines 20 through the fourth vias 120 at the intersections between the horizontal auxiliary lines 602 and the power signal lines 20.

It should be noted that present disclosure is an improvement based on the fanout in Active Area (FIAA) design. Therefore, one may refer to the existing FIAA design for positions not mentioned in the present disclosure.

In some embodiments, spacings between two adjacent horizontal auxiliary lines 602 are same, and/or spacings between two adjacent vertical auxiliary lines 601 are same.

The vertical auxiliary lines 601 are disposed in a layer different from a layer where the reset signal lines 40 are disposed, and the vertical auxiliary lines 601 intersect and are connected with the reset signal lines 40 to form a grid. The horizontal auxiliary lines 602 are disposed in a layer different from a layer where the power signal lines 20 are disposed, and the horizontal auxiliary lines 602 intersect and are connected with the power signal lines 20 to form a grid.

It can be understood that spacings between any two adjacent traces in a same direction in each grid are same, which is beneficial for reducing impedance of the reset signal lines 40 and the power signal lines 20, thereby further improving the display uniformity.

In some embodiments, the OLED display panel includes a plurality of pixel units, and each pixel unit includes two sub-pixels.

The two sub-pixels include a first sub-pixel and a second sub-pixel. The first sub-pixel is a red-green sub-pixel, and the second sub-pixel is a blue-green sub-pixel.

It can be understood that pixel arrangement of the OLED display panel is Pentile arrangement, in which only two sub-pixels are included in one pixel. Since each sub-pixel has one horizontal auxiliary line 602 or one second trace 702, and one vertical auxiliary line 601 or one first trace 701, in this arrangement, one pixel unit only includes two horizontal auxiliary lines 602 or two second traces 702, and two vertical auxiliary lines 601 or two first traces 701.

It should be noted that the following embodiments use the Pentile arrangement as an example. Other pixel arrangements may be applicable to the present disclosure and shall also fall within the protection scope of present disclosure.

In some embodiments, the first fanout traces 70 include the first traces 701 extending along the first direction 130 and the second traces 702 extending along the second direction 140. The first traces 701 are spaced and insulated from the vertical auxiliary lines 601. The second traces 702 are spaced and insulated from the horizontal auxiliary lines 602. First ends of the first traces 701 are electrically connected to the second fanout traces 80, and second ends of the first traces 701 are electrically connected to the second traces 702 through the first vias 90. The second traces 702 are electrically connected to the data signal lines 30 through the second vias 100.

The second traces 702 are disposed in a layer different from a layer where the first traces 701 are disposed. The second traces 702 are disposed in a layer different from a layer where the data signal lines 30 are disposed.

The first traces 701 and the data signal lines 30 may be disposed in a same layer.

It can be understood that the first traces 701 of the first fanout traces 70 may adopt some of the first metal traces, and the second traces 702 of the first fanout traces 70 may adopt some of the second metal traces. The remaining metal traces can be used as the auxiliary traces 60.

Some of the metal traces are used as the first traces 701 and the second traces 702. The second traces 702 are connected respectively to the first traces 701 through the first vias 90 and further to the data signal lines 30 through the second vias 100, which thus realizes a connection across traces through the vias, thereby avoiding the first fanout traces 70 in the display area 1 from being short-circuited.

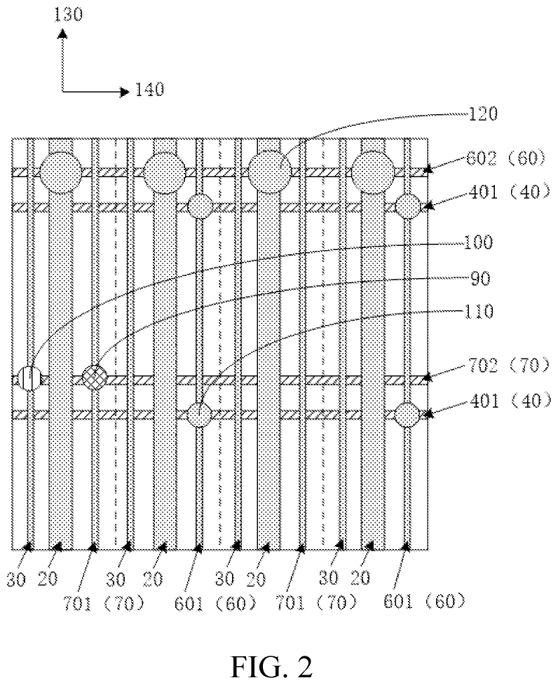

In some embodiments, please refer to FIG. 2, each pixel unit includes one second trace 702 and one horizontal auxiliary line 602. The second traces 702 and the horizontal auxiliary lines 602 are set to be a periodic arrangement in which they alternate with and are spaced apart from each other.

It can be understood that there are only two second metal traces extending along the second direction 140 in any pixel unit, that is to say, in any pixel unit, one of the two second metal traces serves as the second trace 702 to connect the first trace 701 and the data signal line 30, and the other of the two second metal traces serves as the horizontal auxiliary line 602, which is connected with the power signal lines 20 in parallel extending along the first direction 130 at the intersections therebetween. For multiple pixel units, the horizontal auxiliary lines 602 and the power signal lines 20 form a grid in a top view direction perpendicular to the substrate 10.

Since the second traces 702 and the horizontal auxiliary lines 602 are set to be a periodic arrangement in which they alternate with and are spaced apart from each other, by providing each pixel unit with one horizontal auxiliary line 602, the display uniformity of the OLED display panel is further improved.

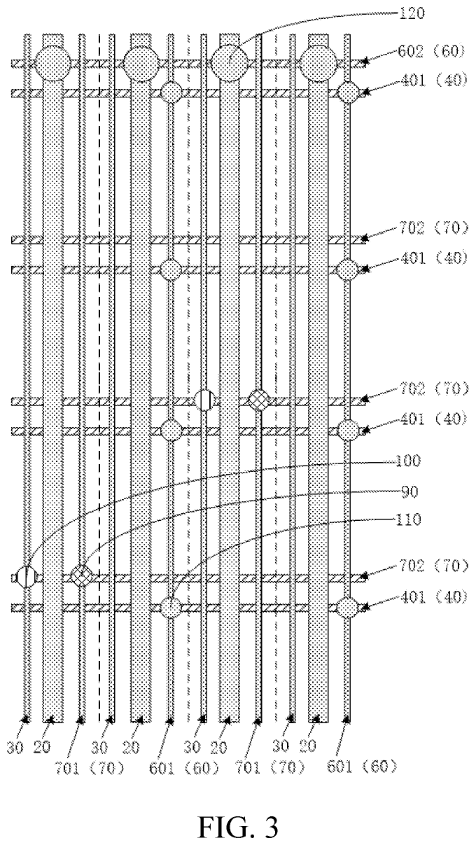

In some other embodiments, please refer to FIG. 3, two adjacent pixel units include three second traces 702 and one horizontal auxiliary line 602.

It can be understood that in another design method of arranging the second traces 702 and the horizontal auxiliary lines 602, every fourth second metal trace is used as the horizontal auxiliary line 602, and the other three are used as the second traces 702. That is to say, in any two adjacent pixel units, there are four second metal traces extending along the second direction 140, three of which serve as the second traces 702 to connect the first traces 701 and the data signal lines 30, and one of which serves as the horizontal auxiliary line 602. The horizontal auxiliary line 602 is connected with the power signal lines 20 in parallel extending along the first direction 130 at the intersections therebetween. For multiple pixel units, the horizontal auxiliary lines 602 and the power signal lines 20 form a grid in a top view direction perpendicular to the substrate 10.

It should be noted that an intersection refers to an overlapping position of two lines arranged in different layers in a direction perpendicular to the substrate 10. For example, the intersections between the horizontal auxiliary lines 602 and the power signal lines 20 refer to the overlapping positions of the horizontal auxiliary lines 602 and the power signal lines 20 in the direction perpendicular to the substrate 10.

Since only one horizontal auxiliary line 602 is provided in one of the two adjacent pixel units, three second traces 702 may be provided in every two adjacent pixel units. Since the arranged second traces 702 are denser, a space for the arrangement of the second traces 7 is reduced, which improves a space for arranging the reset signal lines 40 extending along the second direction 140, thereby improving space utilization.

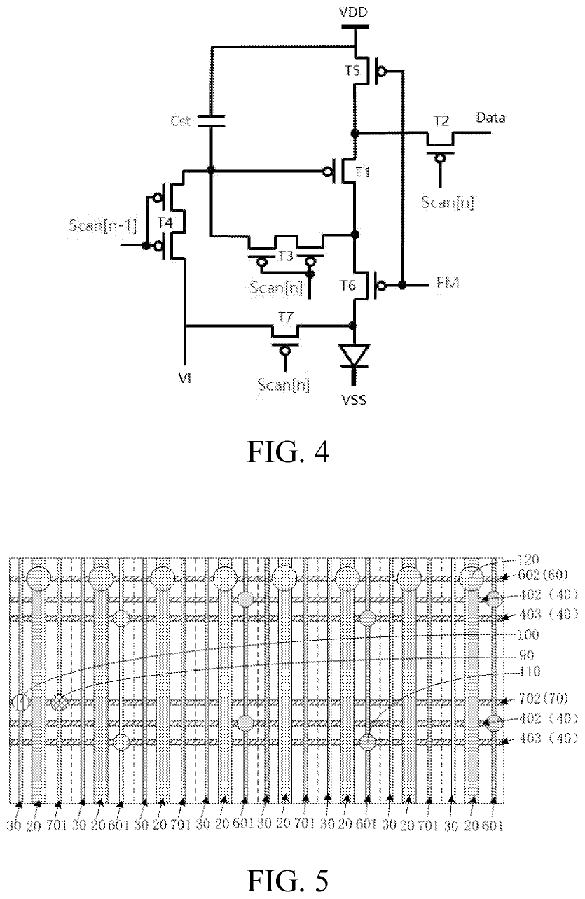

In some embodiments, please refer to FIGS. 2 and 4, the OLED display panel includes a single-reset-signal pixel drive circuit, where the reset signal lines 40 are the first reset signal lines 401, and each pixel unit further includes one first trace 701 and one vertical auxiliary line 601. In each pixel unit, the vertical auxiliary line 601 is connected with the first reset signal lines 401 in parallel at the intersections therebetween.

The single-reset-signal pixel drive circuit is a seven-transistor-one-capacitor (7T1C) circuit as shown in FIG. 4. The single-reset-signal pixel drive circuit only includes one reset signal line 40. A specific connection relationship of the single-reset-signal pixel drive circuit can be seen in FIG. 4, which is not detailed herein.

It can be understood that any pixel unit includes two first metal traces, one of the first metal traces is used as the first trace 701 to connect the second fanout trace 80 and the data signal line 30, the other one of the first metal traces is used as the vertical auxiliary line 601 to connect with the first reset signal lines 401 to reduce the impedance of the first reset signal lines 401. That is to say, for the single-reset-signal pixel drive circuit, when the vertical auxiliary lines 601 are set to be a periodic arrangement, a minimum period of the arrangement of the vertical auxiliary lines 601 is set to be two adjacent first metal traces extending along the first direction 130.

By arranging one of the two first metal traces in any pixel unit as the first trace 701 and the other one of the two first metal traces as the vertical auxiliary line 601, the number of unused first metal traces is further reduced and a utilization rate of the first metal traces is improved, which is conducive to further achieving a narrow border and reducing a cost.

Further, in some embodiments, every fourth, sixth, or eighth first metal trace of the first metal traces is used as one vertical auxiliary line 601, and the vertical auxiliary line 601 is connected with the first reset signal lines 401 in parallel at the intersections between the vertical auxiliary line 601 and the first reset signal lines 401.

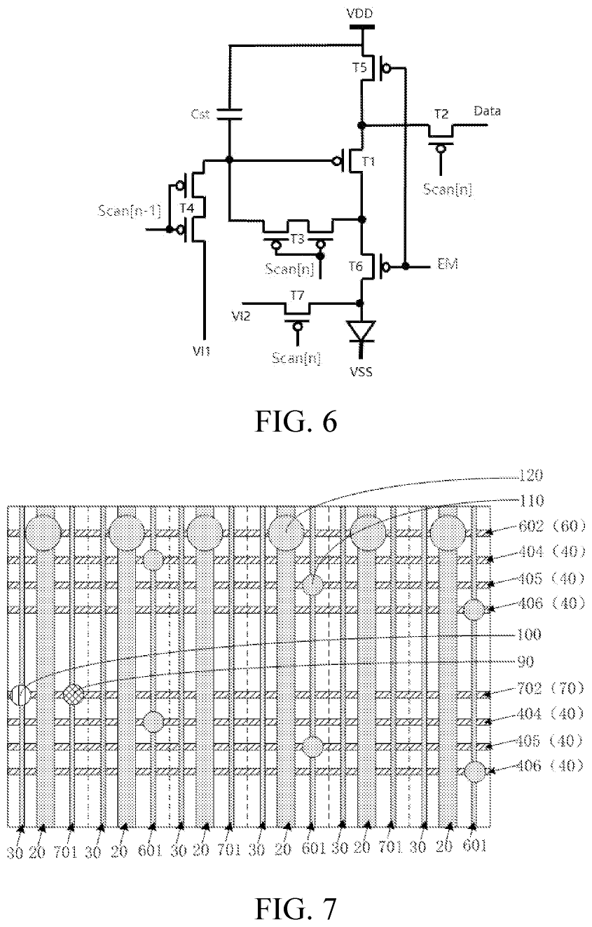

In some embodiments, please refer to FIGS. 5 and 6, the OLED display panel includes a dual-reset-signal pixel drive circuit, and the reset signal lines 40 include second reset signal lines 402 and third reset signal lines 403. Each of the pixel units includes one first trace 701 and one vertical auxiliary line 601. For two adjacent pixel units, one vertical auxiliary line 601 in one of the two adjacent pixel units is connected with the second reset signal lines 402 in parallel at intersections between the vertical auxiliary line 601 and the second reset signal lines 402, and another vertical auxiliary line 601 in the other one of the two adjacent pixel units is connected with the third reset signal lines 403 in parallel at intersections between the another vertical auxiliary line 601 and the third reset signal lines 403.

The dual-reset-signal pixel drive circuit is a 7T1C circuit as shown in FIG. 6. The dual-reset-signal pixel drive circuit includes two types of reset signal lines 40, i.e., the second reset signal lines 402 and the third reset signal lines 403. The second reset signal lines 402 and the third reset signal lines 403 are only intended to be distinguished from the first reset signal lines 401. These reset signal lines can receive different reset signals or same reset signals. A specific connection relationship of the dual-reset-signal pixel drive circuit can be seen in FIG. 6, which is not detailed herein.

It can be understood that two adjacent pixel units include four first metal traces, and one of the first metal traces in any pixel unit is used as the vertical auxiliary line 601. The vertical auxiliary lines 601 in the two adjacent pixel units are respectively connected with the second reset signal lines 402 and the third reset signal lines 403 in parallel, which reduces the impedance of the second reset signal lines 402 and the third reset signal lines 403. That is to say, for the dual-reset-signal pixel drive circuit, when the vertical auxiliary lines 601 are in a periodic arrangement, the vertical auxiliary lines 601 in two adjacent pixel units need to be respectively connected to different second reset signal lines 402 and third reset signal lines 403. A minimum period of the arrangement of the vertical auxiliary lines 601 is four adjacent first metal traces extending along the first direction 130, two of which serve as the vertical auxiliary lines 601 respectively connected to the second reset signal lines 402 and the third reset signal lines 403.

For the case where the dual-reset-signal pixel drive circuit includes the second reset signal lines 402 and the third reset signal lines 403, by making the four first metal traces in any two adjacent pixel units to have two first metal traces as the first traces 701, one first metal trace as the vertical auxiliary line 601 connected to the second reset signal lines 402, and the last one first metal trace as the vertical auxiliary line 601 connected to the third reset signal lines 403, the number of unused first metal traces is further reduced, and the utilization rate of the first metal traces is improved, which is conducive to further achieving the narrow border and reducing the cost.

Further, in some embodiments, every fourth, sixth, or eighth first metal trace of the first metal traces is used as one vertical auxiliary line 601 of the vertical auxiliary lines 601, and the vertical auxiliary line 601 is connected with the second reset signal lines 402 in parallel at intersections between the vertical auxiliary line 601 and the second reset signal lines 402, or is connected with the third reset signal lines 403 in parallel at intersections between the vertical auxiliary line 601 and the third reset signal lines 403.

It can be understood that the remaining first metal traces can be used to serve as the first traces.

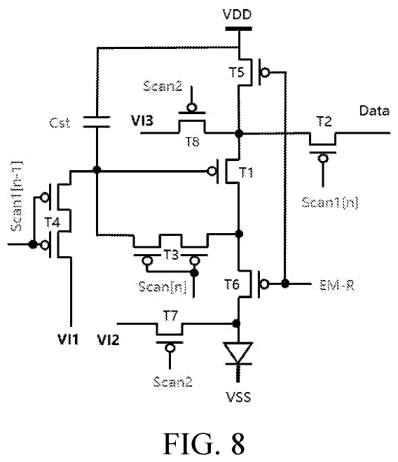

In some embodiments, please refer to FIGS. 7 and 8, the OLED display panel includes a three-reset-signal pixel drive circuit, and the reset signal lines 40 include fourth reset signal lines 404, fifth reset signal lines 405, and sixth reset signal lines 406. Each of the pixel units includes one of the first traces 701 and one of the vertical auxiliary lines 601. For three adjacent pixel units of the pixel units, a vertical auxiliary line 601 in one of the three adjacent pixel units is connected with the fourth reset signal lines 404 in parallel at intersections between the vertical auxiliary line 601 and the fourth reset signal lines 404, another vertical auxiliary line 601 in another one of the three adjacent pixel units is connected with the fifth reset signal lines 405 in parallel at intersections between the another vertical auxiliary line 601 and the fifth reset signal lines 405, and another vertical auxiliary line 601 in another one of the three adjacent pixel units is connected with the sixth reset signal lines 406 in parallel at intersections between the another vertical auxiliary line 601 and the sixth reset signal lines 406.

The three-reset-signal pixel drive circuit is an eight-transistor-one-capacitor (8T1C) circuit as shown in FIG. 8. The three-reset-signal pixel drive circuit includes three types reset signal lines 40, i.e., the fourth reset signal lines 404, the fifth reset signal lines 405, and the sixth reset signal lines 406. The fourth reset signal lines 404, the fifth reset signal lines 405, and the sixth reset signal lines 406 are only intended to be distinguished from the first reset signal lines 401, the second reset signal lines 402, and the third reset signal lines 403. These reset signal lines can receive different reset signals or same reset signals. A specific connection relationship of the three-reset-signal pixel drive circuit can be seen in FIG. 8, which is not detailed herein.

It can be understood that three adjacent pixel units include six first metal traces, and one of the first metal traces in any pixel unit is used as the vertical auxiliary line 601. The vertical auxiliary lines 601 of the three adjacent pixel units are respectively connected with the fourth reset signal lines 404, the fifth reset signal lines 405, and the sixth reset signal lines 406 in parallel, which reduces impedance of the fourth reset signal lines 404, the fifth reset signal lines 405, and the sixth reset signal lines 406. That is to say, for the three-reset-signal pixel drive circuit, when the vertical auxiliary lines 601 are in a periodic arrangement, the vertical auxiliary lines 601 in three adjacent pixel units need to be respectively connected to different fourth reset signal lines 404, fifth reset signal lines 405, and sixth reset signal lines 406, and therefore a minimum period of the arrangement of the vertical auxiliary lines 601 is six adjacent first metal traces extending along the first direction 130, three of which serve as the vertical auxiliary lines 601 respectively connected to the fourth reset signal lines 404, the fifth reset signal lines 405, and the sixth reset signal lines 406.

For the case where the three-reset-signal pixel drive circuit includes the fourth reset signal lines 404, the fifth reset signal lines 405, and the sixth reset signal lines 406, by making the six first metal traces in any three adjacent pixel units to have three first metal traces as the first traces 701, and other three first metal traces as the vertical auxiliary lines 601 respectively connected to the fourth reset signal lines 404, the fifth reset signal lines 405, and the sixth reset signal lines 406, the number of unused first metal traces is further reduced, and the utilization rate of the first metal traces is improved, which is conducive to further achieving the narrow border and reducing the cost.

Further, in some embodiments, every sixth or ninth first metal traces of the first metal traces are used as three vertical auxiliary lines 601, and the three vertical auxiliary lines 601 are respectively connected with the fourth reset signal lines 404, the fifth reset signal lines 405, and the sixth reset signal lines 406 in parallel at intersections therebetween.

In some embodiments, the OLED display panel further includes a first source-drain layer disposed above the substrate 10 and a second source-drain layer disposed on a side of the first source-drain layer away from the substrate 10. The horizontal auxiliary lines 602 and the first source-drain layer are arranged in a same layer, and the vertical auxiliary lines 601 and the second source-drain layer are disposed in a same layer.

At least one of the first source-drain layer and the second source-drain layer is a stacked structure of titanium/aluminum/titanium. The horizontal auxiliary lines 602 and the vertical auxiliary lines 601 formed by the titanium/aluminum/titanium stacked structure have lower impedance, which further improves the display uniformity.

The reset signal lines 40 and the first source-drain layer are disposed in a same layer, and the power signal lines 20 and the second source-drain layer are disposed in a same layer.

The power signal lines 20 may be arranged in the same layer as the second source-drain layer and may be a stacked structure of titanium/aluminum/titanium, thereby further reducing the impedance of the power signal lines 20, reducing a voltage drop, and improving high-brightness display uniformity.

The reset signal lines 40 may be arranged in the same layer as the first source-drain layer and may be a stacked structure of titanium/aluminum/titanium, thereby further reducing the impedance of the reset signal lines 40, reducing a voltage drop, and improving low-grayscale display uniformity.

It can be understood that since the horizontal auxiliary lines 602 and the second traces 702 are both routed using the second metal traces, and the vertical auxiliary lines 601 and the first traces 701 are both routed using the first metal traces, the horizontal auxiliary lines 602 are disposed in the same layer as the second traces 702, and the vertical auxiliary lines 601 are disposed in the same layer as the first traces 701.

By disposing the reset signal lines 40 and the horizontal auxiliary lines 602 in the first source-drain layer, and disposing the power signal lines 20 and the vertical auxiliary lines 601 in the second source-drain layer, the impedance of the reset signal lines 40 and the impedance of the power signal lines 20 are further reduced, which improves the display uniformity.

In some other embodiments, the horizontal auxiliary lines 602 may also be disposed in the same layer as the second source-drain layer, and the vertical auxiliary lines 601 may also be disposed in the same layer as the first source-drain layer.

In some embodiments, the OLED display panel further includes a gate layer disposed above the substrate 10, the first source-drain layer is disposed on a side of the gate layer away from the substrate 10, the power signal lines 20 are disposed in a same layer as the second source-drain layer, and the reset signal lines 40 are disposed in a same layer as the gate layer.

The gate layer further includes gate electrodes, and materials for manufacturing the reset signal lines 40 and the gate electrodes may both include molybdenum.

Furthermore, in some gate layer designs, the gate layer may also adopt a stacked structure of titanium/aluminum/titanium, which may also have the effect of improving conductivity of the reset signal lines 40 and reducing the impedance of the reset signal lines 40, further improving the low-grayscale display uniformity.

It can be understood that when the routing space in the first source-drain layer and the second source-drain layer is insufficient, the reset signal lines 40 and the gate electrodes, which require lower conductivity than the power signal lines 20, can be manufactured in the same layer as the gate electrodes, which makes full use of spare routing space in the gate layer and helps to increase the trace spacing(s) in the first source-drain layer and the second source-drain layer, and reduces a risk of the traces in the first source-drain layer and the second source-drain layer to be short-circuited. In addition, a utilization rate of the routing space in the gate layer may be improved.

By arranging the reset signal lines 40, which have a lower conductivity requirement than the power signal lines 20, in the same layer as the gate layer, the utilization rate of the routing space in the OLED display panel is improved, and the risk of the traces in the first source-drain layer and the second source-drain layer to be short-circuited is reduced.

In the present disclosure, the metal traces are preset in the first area 3 of the display area 1. Some of the metal traces are used as the first fanout traces 70 of the display area 1, and the remaining unused metal traces are used as the auxiliary traces 60. The auxiliary traces 60 include vertical auxiliary lines 601 extending along the first direction 130 and horizontal auxiliary lines 602 extending along the second direction 140. The vertical auxiliary lines 601 extending along the first direction 130 and the reset signal lines 40 extending in the second direction 140 are connected in parallel at the intersections to form a grid, which is used to reduce the impedance of the reset signal lines 40 and thus improve the low-grayscale display uniformity. The horizontal auxiliary lines 602 extending along the second direction 140 and the power signal lines 20 extending along the first direction 130 are connected in parallel at the intersections to form a grid, which is used to reduce the impedance of the power signal lines 20 to improve the high-brightness display uniformity. Therefore, the horizontal auxiliary lines 602 and the power signal lines 20 are electrically connected at the intersections to form a grid-like connection, and/or the vertical auxiliary lines 601 and the reset signal lines 40 are electrically connected at the intersections to form a grid-like connection, thereby improving at least one of the low-grayscale display uniformity and the high-brightness display uniformity of the OLED display panel.

The present disclosure further proposes a display module and a terminal device. The display module and the terminal device both include the above-mentioned OLED display panel, which will not be described again here. The display module further includes at least one of a back plate, a cover, and an optical film. The terminal device includes but is not limited to mobile phones, notebook computers, and tablet computers.

The OLED display panel provided by some embodiments of the present disclosure has a display area and a non-display area. The OLED display panel includes a substrate, and a plurality of power signal lines, a plurality of data signal lines, a plurality of reset signal lines, a plurality of fanout traces, and a plurality of auxiliary traces. The power signal lines, the data signal lines, the reset signal lines, the fanout traces, and the auxiliary traces are disposed above the substrate. The fanout traces include a plurality of first fanout traces and a plurality of second fanout traces. The first fanout traces are arranged in a first area of the display area. The second fanout traces are arranged in the non-display area. First ends of the first fanout traces are electrically connected to the data signal lines, and second ends of the first fanout traces are electrically connected to the second fanout traces. The auxiliary traces include a plurality of vertical auxiliary lines and a plurality of horizontal auxiliary lines, where the vertical auxiliary lines are disposed in a layer different from a layer where the horizontal auxiliary lines are disposed. The vertical auxiliary lines and the power signal lines extend along a first direction. The horizontal auxiliary lines and the reset signal lines extend along a second direction. The first direction and the second direction are perpendicular to each other. The horizontal auxiliary lines are disposed in a layer different from a layer where the power signal lines are disposed. The vertical auxiliary lines are disposed in a layer different from a layer where the reset signal lines are disposed. The horizontal auxiliary lines in parallel are electrically connected to the power signal lines in parallel at intersections therebetween, and/or the vertical auxiliary lines in parallel are electrically connected to the reset signal lines in parallel at intersections therebetween. By forming the grid-like connection(s) between the auxiliary traces and the power signal lines and/or the reset signal lines, the impedance of the power signal lines and/or the reset signal lines is reduced, thereby improving display uniformity.

In the above embodiments, each embodiment is described with its own emphasis. For parts that are not described in detail in a certain embodiment, please refer to the relevant descriptions of other embodiments.

The OLED display panel provided by the embodiments of the present disclosure has been introduced in detail above. Specific embodiments are used in the present disclosure to illustrate the principles and implementation methods of the present disclosure. The description of the above embodiments is only used to help understand the methods of the present disclosure and the core idea. At the same time, for those skilled in the art, there will be changes in the specific implementation and an application scope based on the ideas of the present disclosure. In summary, the content of this description should not be understood as a limitation of the present disclosure.

What is claimed is:

1. An organic light emitting diode (OLED) display panel having a display area and a non-display area, comprising:
a substrate;
a plurality of power signal lines, a plurality of data signal lines, a plurality of reset signal lines disposed above the substrate;
a plurality of fanout traces disposed above the substrate, wherein the fanout traces comprises a plurality of first fanout traces and a plurality of second fanout traces, the first fanout traces are arranged in the display area, the second fanout traces are arranged in the non-display area, first end of each first fanout trace is electrically connected to one data signal line of the data signal lines, and second end of the each first fanout trace is electrically connected to one second fanout trace of the second fanout traces; and
a plurality of auxiliary traces disposed as an array in the display area above the substrate, wherein the auxiliary traces comprise a plurality of vertical auxiliary lines and a plurality of horizontal auxiliary lines, the vertical auxiliary lines are disposed in a layer different from a layer where the horizontal auxiliary lines are disposed, the vertical auxiliary lines and the power signal lines extend along a first direction, the horizontal auxiliary lines and the reset signal lines extend along a second direction, and the first direction and the second direction are perpendicular to each other;
wherein the horizontal auxiliary lines are disposed in a layer different from a layer where the power signal lines are disposed, the vertical auxiliary lines are disposed in a layer different from a layer where the reset signal lines are disposed, and
the horizontal auxiliary lines in parallel are electrically connected with the power signal lines in parallel at intersections therebetween, and/or the vertical auxiliary lines in parallel are electrically connected to the reset signal lines in parallel at intersections therebetween to form a grid-like connection.

2. The OLED display panel of claim 1, further comprising a plurality of pixel units, wherein each pixel unit comprises two sub-pixels.

3. The OLED display panel of claim 2, wherein the display area comprises a plurality of metal traces,
the metal traces comprise a plurality of first metal traces extending along the first direction and a plurality of second metal traces extending along the second direction,
some of the first metal traces are used as a plurality of first traces and some of the second metal traces are used as a plurality of second traces,
the first fanout traces comprise the first traces extending along the first direction and the second traces extending along the second direction, and
remaining metal traces of the plurality of metal traces that are not used as the first fanout traces are used as the auxiliary traces, in which remaining first metal traces that are not used as the first traces are used as the vertical auxiliary lines, and remaining second metal traces that are not used as the second traces are used as the horizontal auxiliary lines.

4. The OLED display panel of claim 3, wherein the first traces are spaced and insulated from the vertical auxiliary lines, the second traces are spaced and insulated from the horizontal auxiliary lines,
first end of each first trace is electrically connected to one said second fanout trace, and second end of the each first trace is electrically connected to one said second trace through a first via, and
each second trace is electrically connected to one said data signal line through a second via.

5. The OLED display panel of claim 4, wherein each pixel unit comprises one said second trace and one said horizontal auxiliary line, and the second traces and the horizontal auxiliary lines are set to be a periodic arrangement in which the second traces and the horizontal auxiliary lines alternate with and are spaced apart from each other.

6. The OLED display panel of claim 4, wherein two adjacent said pixel units comprise three said second traces and one said horizontal auxiliary line.

7. The OLED display panel of claim 5, further comprising a single-reset-signal pixel drive circuit, and
wherein the reset signal lines are a plurality of first reset signal lines, and each pixel unit further comprises one said first trace and one said vertical auxiliary line.

8. The OLED display panel of claim 7, wherein in each pixel unit, one said vertical auxiliary line are connected with the first reset signal lines in parallel at intersections between the vertical auxiliary line and the first reset signal lines.

9. The OLED display panel of claim 7, wherein every fourth, sixth, or eighth first metal trace of the first metal traces is used as the vertical auxiliary line, the vertical auxiliary line being connected with the first reset signal lines in parallel at intersections between the vertical auxiliary line and the first reset signal lines.

10. The OLED display panel of claim 5, further comprising a dual-reset-signal pixel drive circuit,
the reset signal lines comprise second reset signal lines and third reset signal lines,
each pixel unit comprises one said first trace and one said vertical auxiliary line,
for two adjacent pixel units, the vertical auxiliary line in one of the two adjacent pixel units is connected with the second reset signal lines in parallel at intersections between the vertical auxiliary line and the second reset signal lines, and the vertical auxiliary line in another one of the two adjacent pixel units is connected with the third reset signal lines in parallel at intersections between the vertical auxiliary line and the third reset signal lines.

11. The OLED display panel of claim 10, wherein every fourth, sixth, or eighth first metal trace of the first metal traces is used as one said vertical auxiliary line, and
the vertical auxiliary line is connected with the second reset signal lines in parallel at intersections between the vertical auxiliary line and the second reset signal lines, or is connected with the third reset signal lines in parallel at intersections between the one vertical auxiliary line and the third reset signal lines.

12. The OLED display panel of claim 5, further comprising a three-reset-signal pixel drive circuit,
wherein the reset signal lines comprise fourth reset signal lines, fifth reset signal lines, and sixth reset signal lines, and
each pixel unit further comprises one said first trace and one said vertical auxiliary line.

13. The OLED display panel of claim 12, wherein for three adjacent pixel units of the pixel units, the vertical auxiliary line in one of the three adjacent pixel units is connected with the fourth reset signal lines in parallel at intersections between the vertical auxiliary line and the fourth reset signal lines,
the vertical auxiliary line in another one of the three adjacent pixel units is connected with the fifth reset signal lines in parallel at intersections between the vertical auxiliary line and the fifth reset signal lines, and
the vertical auxiliary line in another one of the three adjacent pixel units is connected with the sixth reset signal lines in parallel at intersections between the vertical auxiliary line and the sixth reset signal lines.

14. The OLED display panel of claim 13, wherein three of every nine adjacent first metal traces of the first metal traces are used as three said vertical auxiliary lines, and the three vertical auxiliary lines are respectively connected with the fourth reset signal lines, the fifth reset signal lines, and the sixth reset signal lines in parallel at intersections between the three vertical auxiliary lines and the fourth reset signal lines, the fifth reset signal lines, and the sixth reset signal lines.

15. The OLED display panel of claim 1, further comprising a first source-drain layer disposed above the substrate and a second source-drain layer disposed on a side of the first source-drain layer away from the substrate, and
wherein the horizontal auxiliary lines and the first source-drain layer are arranged in a same layer, and the vertical auxiliary lines and the second source-drain layer are disposed in a same layer.

16. The OLED display panel of claim 15, wherein the reset signal lines and the first source-drain layer are disposed in a same layer, and the power signal lines and the second source-drain layer are disposed in a same layer.

17. The OLED display panel of claim 15, further comprising a gate layer disposed above the substrate, wherein the first source-drain layer is disposed on a side of the gate layer away from the substrate, the power signal lines and the second source-drain layer are disposed in a same layer, and the reset signal lines and the gate layer are disposed in a same layer.

18. The OLED display panel of claim 15, wherein at least one of the first source-drain layer and the second source-drain layer is a stacked structure of titanium/aluminum/titanium.

19. The OLED display panel of claim 1, wherein spacings between any two adjacent said horizontal auxiliary lines are same, and/or spacings between any two adjacent said vertical auxiliary lines are same.

20. A terminal device, comprising an organic light emitting diode (OLED) display panel, wherein the OLED display panel comprises:
a substrate;
a plurality of power signal lines, a plurality of data signal lines, a plurality of reset signal lines disposed above the substrate;
a plurality of fanout traces disposed above the substrate, wherein the fanout traces comprises a plurality of first fanout traces and a plurality of second fanout traces, the first fanout traces are arranged in the display area, the second fanout traces are arranged in the non-display area, first end of each first fanout trace is electrically connected to one data signal line of the data signal lines, and second end of the each first fanout trace is electrically connected to one second fanout trace of the second fanout traces; and
a plurality of auxiliary traces disposed as an array in the display area above the substrate, wherein the auxiliary traces comprise a plurality of vertical auxiliary lines and a plurality of horizontal auxiliary lines, the vertical auxiliary lines are disposed in a layer different from a layer where the horizontal auxiliary lines are disposed, the vertical auxiliary lines and the power signal lines extend along a first direction, the horizontal auxiliary lines and the reset signal lines extend along a second direction, and the first direction and the second direction are perpendicular to each other;
wherein the horizontal auxiliary lines are disposed in a layer different from a layer where the power signal lines are disposed, the vertical auxiliary lines are disposed in a layer different from a layer where the reset signal lines are disposed, and
the horizontal auxiliary lines in parallel are electrically connected with the power signal lines in parallel at intersections therebetween, and/or the vertical auxiliary lines in parallel are electrically connected to the reset signal lines in parallel at intersections therebetween to form a grid-like connection.
